(19) United States
(12) Patent Application Publication
(10) Pub. No.: US 2008/0086246 A1
(43) Pub. Date: Apr. 10, 2008

(54) Portable vehicle powering and testing systems

(76) Inventors: Scott Bolt, New Hudson, MI (US); Issac Nielsen, Farmington Hills, MI (US)

Correspondence Address: BLISS MCGLYNN, P.C., 2075 WEST BIG BEAVER ROAD, SUITE 600, TROY, MI, 48084, US

(21) Appl. No.: 11/906,832

(22) Filed: Oct. 4, 2007

Related U.S. Application Data
(60) Provisional application No. 60/849,243, filed on Oct. 4, 2006.

(51) Int. Cl. G01R 31/00

(52) U.S. Cl. 701/29

(57) ABSTRACT

A portable system for powering and testing the electrical circuits of a vehicle comprising a source of electrical power adapted to power the system and to provide electrical power to the vehicle. A power connector is adapted to quickly connect/disconnect the system to/from the electrical system of the vehicle. A diagnostic connector is adapted to quickly connect/disconnect the system to/from the electrical circuits of the vehicle being tested. A portable, low-power, sealed computing device is adapted to perform testing on the electrical circuits of the vehicle. A vehicle-communications interface is in electrical communication with the computing device and diagnostic connector that is adapted to provide electrical interface between the computing device and the electrical circuits of the vehicle.

### CROSS-REFERENCE TO RELATED APPLICATIONS

This application claims the benefit of provisional application U.S. Ser. No. 60/849,243 entitled “Portable Vehicle Powering and Testing System,” filed Oct. 4, 2006.

### BACKGROUND OF THE INVENTION

1. Field of the Invention

The present invention relates generally to powering and testing of electronic systems of a vehicle and, in particular, to a portable vehicle powering and testing system.

2. Description of the Related Art

Testing of vehicles in an assembly plant has evolved over the years as electronic systems of the respective vehicles have become more complex. For example, it is no longer unusual for a vehicle to have fifty to one hundred computer modules on it. Each of these modules must be programmed, configured, and tested during the vehicle build process. Time needed for such programming, configuration, and testing has grown to the point that many stations within a production line are now needed in order to accomplish these tasks.

Product build problems like improperly touted wiring, incorrect wire harnesses, incorrect module connection, or faulty computer modules, etc. are very costly and time-consuming to repair after the vehicle has been fully assembled. More specifically, seats, upholstery, and body molding of the vehicle that cover wiring and modules make it difficult to repair these issues after the vehicle has been substantially built out. As such, it is desirable for testing of these modules to be performed early in the assembly of the vehicle.

On the other hand, because the vehicle battery can be drained by power usage during the vehicle build process, the battery is not put into the vehicle until quite late in its assembly. Thus, system testing during vehicle build typically requires a separate power source, usually as a rail-based power supply. Unfortunately, these rail-based power supplies require much floor space, expense, and additional man-power within the assembly plant. Additionally, to provide a more portable system, wet-cell batteries similar to those ultimately installed in the vehicles are impracticable to utilize given their size and weight. Furthermore, utilizing common configurations of rechargeable and more portable battery types has proven impracticable due to limitations of current control, heat dissipation, and electromagnetic interference with testing devices.

Accordingly, there is a need in the related art for a system that can test electronic systems of a vehicle in early stages of assembly of the vehicle. There is also a need in the related art for such a system that can supply power to the vehicle during testing. There is also a need in the related art for such a system that eliminates the requirement for a separate rail-based power supply to be used to power the vehicle for such testing. There is also a need in the related art for such a system that reduces the amount of floor space and man-power required within the assembly plant for such testing. There is also a need in the related art for a system that can provide the necessary power to the vehicle, perform the required testing, be easily portable, be rechargeable, and overcome the physical and electrical limitations of current control, heat dissipation, and electromagnetic interference (EMI).

### SUMMARY OF THE INVENTION

The present invention overcomes the disadvantages in the related art in a portable system for powering and testing the electrical circuits of a vehicle comprising a source of electrical power adapted to power the system and to provide electrical power to the vehicle. A power connector is adapted to quickly connect/disconnect the system to/from the electrical system of the vehicle. A diagnostic connector is adapted to quickly connect/disconnect the system to/from the electrical circuits of the vehicle being tested. A portable, low-power, sealed computing device is adapted to perform testing on the electrical circuits of the vehicle. A vehicle-communications interface is in electrical communication with the computing device and diagnostic connector that is adapted to provide electrical interface between the computing device and the electrical circuits of the vehicle.

In this manner, the portable system for powering and testing a vehicle of the present invention can test electronic systems of a vehicle at any stage of assembly of the vehicle. In one embodiment, the source of electrical power for the system of the present invention includes a portable rechargeable lithium battery pack and a current limiter in electrical communication with the electrical source and the power connector. The current limiter is adapted to control the power output of the electrical source for protection of the electrical circuits of the vehicle, and further includes a current monitor circuit that is adapted to monitor the current flowing to and from the electrical source and reduce EMI emissions, and a battery protection circuit that is adapted to prevent overcharging and line surges that may damage the electrical source.

Thus, the present invention eliminates the requirement for a separate rail-based power supply to be used to power the vehicle for such testing and reduces the amount of floor space and man-power required within the assembly plant for such testing and overcomes the limitations of the related art regarding current control, heat dissipation, and electromagnetic interference.

Other objects, features, and advantages of the present invention will be readily appreciated as the same becomes better understood after reading the subsequent description taken in conjunction with the accompanying drawings.

### BRIEF DESCRIPTION OF THE DRAWINGS

FIG. 1 is a perspective view of an embodiment of the portable system for powering and testing a vehicle of the present invention;

FIG. 2 is a representative cross-section side view of the of the portable system of the present invention shown in FIG. 1 illustrating the general physical component locations, respectively;

FIG. 3 is a perspective view of one operative embodiment of the portable system illustrated in FIG. 1 showing the system operatively connected to the vehicle via the cigarette lighter;

FIG. 3A is a perspective view of another operative embodiment of the portable system of the present invention illustrated in FIG. 1 shown with power connection cables adapted for connecting the system to the vehicle power connection points;

FIG. 4 is a perspective view of the scanning unit of the portable system of the present invention shown in FIG. 1;

FIG. 5 is an end view of the embodiment of the portable system of the present invention shown in FIG. 1; and

FIG. 6 schematic block diagram of the embodiment of the portable system of the present invention shown in FIG. 1.

### DETAILED DESCRIPTION OF THE INVENTION

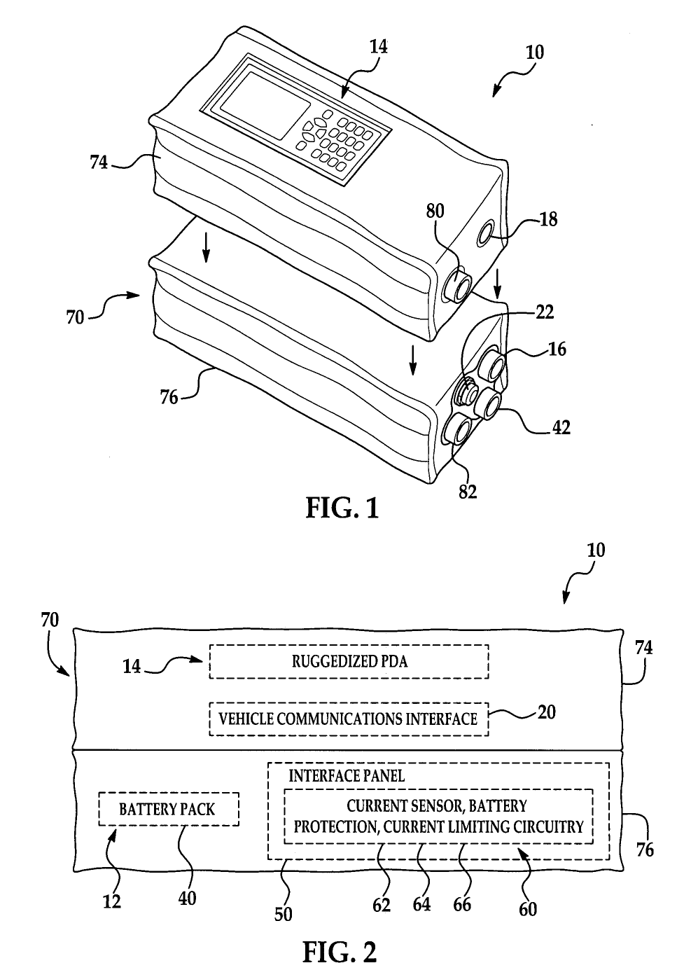

Referring now to the figures, where like numerals are used to designate like structure, a portable system for powering and testing a vehicle of the present invention is generally indicated at 10 in FIGS. 1 through 6. It should be appreciated by those having ordinary skill in the related art that the system 10 can be employed with any suitable type of vehicle.

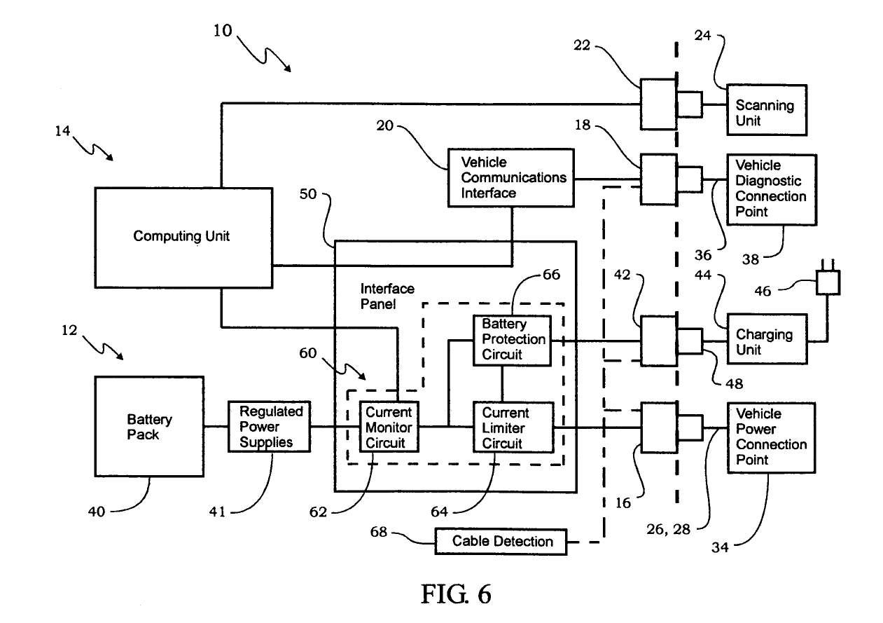

As shown in FIGS. 1 and 6, the system 10 includes a source of electrical power, generally indicated at 12, adapted to power both the portable system itself and to provide direct electrical power to the vehicle. A portable, ruggedized, low-power, sealed computing device, generally indicated at 14, is adapted to perform testing on the electrical circuits of the vehicle. The computing device 14 is capable of storing various repeatable programs for testing the vehicle's circuits. It should be appreciated by those of ordinary skill in the art that the computing unit 14 may also be utilized to download specific programming to devices installed in the vehicle.

A power connector 16 is adapted to quickly connect and disconnect the portable system 10 to and from the electrical system of the vehicle. A diagnostic connector 18 is adapted to quickly connect and disconnect the portable system 10 to and from the electrical circuits of the vehicle being tested. It should be appreciated that the portable system 10 may be configured to include more than one power connector 16 and more than one diagnostic connector 18. A vehicle-communications interface 20 is in electrical communication with the computing device 14 and the diagnostic connector 18. The vehicle-communications interface 20 is adapted to provide electrical interface between the computing device 14 and the electrical circuits of the vehicle.

As shown in FIGS. 4 and 5, the portable system 10 further includes a scanning unit connector 22 and a scanning unit 24. The scanning unit connector 22 is adapted to quickly connect and disconnect the scanning unit 24 to and from the portable system 10. In the preferred embodiment, the scanning unit 24 is a hand-held unit adapted to scan and electrically recognize standardized barcodes. This is a useful feature in combination with stored testing programs within the computing device 14. More specifically, a vehicle on the assembly line has an accompanying “build sheet” that lists all the options and equipment to be installed on the particular vehicle as it progresses along the line. It is becoming standard practice to also barcode the build sheet information to allow machine scanning of the information. In this manner, when performing line testing on a vehicle, the operator of the portable system 10 can scan the vehicle barcode with the scanning unit 24 and, based on the programming of the computing device 14, the portable system 10 would load the only testing programs needed for that vehicle and no others. Furthermore, given that information, the computing device 14 can quickly inform the portable system operator of the necessary interconnection cables that are needed to test that particular vehicle. In like manner, if the portable system 10 is also being used to download programming into devices installed in the vehicle, the barcode scanning can quickly and efficiently identify the specific programs needed.

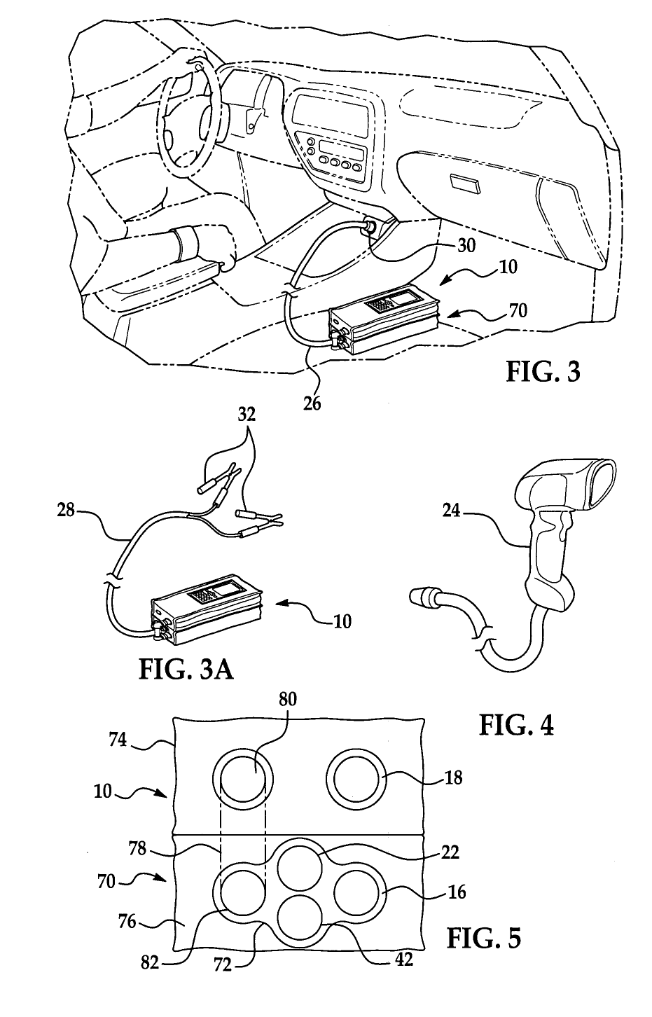

The power connector 16 is utilized to provide a connection to some portion of the vehicle's electrical system to power the various circuits and electrical components that are under test within the vehicle. Since it is desirable to use the portable system 10 on the vehicle assembly line at various stages of assembly, the vehicle will generally have only a portion of its electrical system installed or operatively connected. Thus, it should be appreciated that the system 10 may utilize power connection cables, as shown as 26 and 28 in FIGS. 3 and 3A. Cable 26 is constructed so as to connect to the power connector 16 on one end and to electrically connect to the vehicle through a cigarette lighter style connector 30 on the other end. Similarly, cable 28 is constructed so as to connect to the power connector 16 on one end and to electrically connect to the vehicle through alligator style clips 32 on the other end. It should be so appreciated that the clips 32 may be connected to various vehicle power connection points (illustrated as 34 in FIG. 6) throughout the vehicle or its wiring depending upon the circumstances at that particular time in the assembly process. It should also be so appreciated that the power clips 32 can be connected to the “positive” and “negative” battery-post cables that would normally be connected to the vehicle battery if one were present. It should be further appreciated that, as illustrated, these two styles of power connections are not limiting and that any of a variety of other electrically connective means may be used. It should also be appreciated that the power connector cables 26, 28 can include any suitable customer-specified vehicle-harness connector. More specifically, a customer can request that the system 10 power the vehicle by connecting it to any suitable harness connector.

To provide the desired testing of, and/or downloading of stored programming to the components of the vehicle, an operative electrical connection must be made between the computing unit 14 and the electrical circuits of the vehicle. Additionally, proper analog and digital modes of communication must be established between the computing unit 14 and the vehicle's circuitry and components. This is accomplished by the vehicle-communications interface 20. As best shown in FIG. 6, the vehicle-communications interface 20 is in electrical communication with the computing device 14 and the diagnostic connector 18. The vehicle-communications interface 20 is adapted to provide electrical interface between the computing device 14 and the electrical circuits of the vehicle. More specifically, the vehicle-communications interface 20 is configured to align and or convert the communication modes of the computing device 14 and the vehicle's circuitry so that they are compatible. For example, the vehicle under test may employ a network communications system between it components, such as a CAN system or twisted-pair cabling and the vehicle-communications interface 20 is capable of converting and controlling the data flow between the vehicle's network system and the computing device 14.

To provide the electrical connection for testing, a variety of diagnostic interface cables (illustrated schematically as 36 in FIG. 6) may be employed that connect first to the diagnostic connector 18 and then connect to a vehicle diagnostics connection point (illustrated schematically as 38 in FIG. 6). Depending upon the specific application and the specific test to be performed, the vehicle may use only one or have a plurality of diagnostic connection points. For example, one vehicle may employ numerous devices requiring testing at a variety of diagnostic connection point throughout the vehicle. In another example, a vehicle may interconnect all its components on a network such that only one diagnostics connection point, such as an “OBD II (J1962) interface would be necessary.

In one embodiment of the system 10 illustrated in FIGS. 1 through 6, the source of electrical power 12 is provided by a rechargeable four-cell lithium poly-battery pack 40 providing about 14.4 volts and a corresponding current. As shown in FIG. 6, the portable system 10 further includes a charging connector 42, and a charging unit 44 that are used to support the rechargeable battery pack 40. The charging unit 44 that is adapted to electrically connect to an electrical source, such as a 115VAC source by plug 46 for example, and to further electrically connect to the charging connector 42 by plug 48 when the system 10 is not connected to a vehicle. In this manner, the charging unit 44 converts the source power to the proper voltage and current to recharge the battery pack 40 when the portable system 10 is not in use. It should be appreciated that the rechargeable battery pack 40 can provide any suitable amount of power and corresponding current. This is accomplished by the use of associated circuitry consisting of a group of regulated power supplies, shown at 41 in FIG. 6. The components of the system 10 have different power requirements than what the batteries can supply by themselves. More specifically, to operate, the system 10 internally requires +12 volts, −12 volts, and +5 volts. The system 10 is also capable of providing these different voltages to the vehicle itself as required.

As best illustrated in FIG. 6, the portable system 10 further includes an interface panel 50 having electrical communication with the source of electrical power 12, the computing device 14, the power connector 16, the diagnostic connector 18, and the vehicle communications interface 20. The interface panel 50 is adapted to control the interface between the source of electrical power 12, the computing device 14, and the power connector 16. More specifically, with a battery pack 40 installed as in the above-mentioned embodiment, the interface panel 50 provides power from the battery pack 40 to both operate the computing device 14 and provide power to the vehicle electrical systems through the power connector 16. Additionally, the interface panel 50 is adapted to control the interface between the computing device 14, the diagnostic connector 18, and the vehicle communications interface 20. More specifically, the interface panel 50 provides electrical communication between the computing device 14 and the diagnostic connector 18 while providing power from the battery pack 40 to operate the vehicle communications interface 20.

The portable system 10 further includes a current limiter, generally indicated at 60, in electrical communication with the electrical source 12 and the power connector 16. The overall function of the current limiter 60 is to switch the battery power on and off to the vehicle, monitor the supplied current and respond accordingly to the vehicle electrical load, and clamp the current output to a preset value if the load draws too much current for the application. The current limiter 60 includes a current monitor circuit 62, a current limiter circuit 64, and a battery protection circuit 66. The current monitor circuit 62 is adapted to monitor the current flowing to and from the electrical source 12, which is a battery pack 40 in the above mentioned embodiment. The current limiter circuit 64 is adapted to control power output of the electrical source 12 for protection of the electrical circuits of the vehicle. The battery protection circuit 66 is adapted to prevent overcharging and line surges that may damage the electrical source 12. Additionally, protection for the components of the system 10 is provided by cable detection feedback of the connections made between the system 10 connectors and external wiring and devices. This is illustrated as block 68 in FIG. 6. In one embodiment, the current limiter 60 is designed around “hot swap” capable integrated circuit chips, which allow connection and disconnection of the power and diagnostic connectors 16, 18 without powering down the portable system 10. This allows the operator of the portable system 10 to move quickly and efficiently between the vehicles on the assembly line. Additionally, this type of circuit design also reduces EMI and prevents excessive heat build-up thereby extending the operative like of the portable system 10 components.

As best shown in FIGS. 1 and 2, an enclosure, generally indicated at 70, encloses the computing device 14, the vehicle-communications interface 20, the battery pack 40, the interface panel 50, and the current limiter 60. One embodiment of the system 10 includes a material that fills substantially all of the resulting space defined within the enclosure 70. More specifically, the material is a high-density foam (not shown) that is employed to pack and mount these components within the enclosure 70. The enclosure 70 is a soft case that is designed to be scratch-free with respect to painted surfaces of the vehicle. The enclosure 70 may be made of a stain-resistant industrial material and includes a plurality of openings 72 for the power connector 16, the diagnostic connector 18, the scanning unit connector 22, and the charging connector 42. As shown in FIGS. 1 and 2, the enclosure 70 may be constructed in two stackable parts, the computing unit section 74 and the battery pack section 76. This allows for easy separation of the computing unit 14 and its associated components from the battery pack 40 and its associated components for maintenance and easy reconfiguration. As illustrated in FIG. 5, each section 74, 76 has a quick connect/disconnect connector, 80 and 82, respectively to provide interconnection between the system 10 sections 72, 74. In the illustrated embodiment, the electrical connections between the system 10 sections are in electrical communication by way of connection cable 78. It should be appreciated that cable 76 may be designed as any suitable type of interface, such as a serial, USB, or ethernet cable, for example.

In operation in a plant where the vehicle is being assembled, the system 10 is self-powered and supplies power to the vehicle via the cigarette lighter, battery cables, or other power connection point to test the electronic systems in the early stages of the assembly. More specifically, at a respective station within a production line, the system 10 tests each of the fifty to one hundred computer modules on the vehicle for integrity of control of its systems and sub-systems. Any issues with the vehicle wiring or installed components, such as improperly routed wiring, incorrect wire harnesses, incorrect module connection, bad modules, or the like, that are uncovered as a result of the test can then be repaired.

Thus, the portable system 10 of the present invention overcomes the limitations of the present art by providing the capability to test the electronic systems of a vehicle in any stage of its assembly, and by supplying the required power to the vehicle for such testing. This eliminates the requirement for a separate rail-based power supply to be used to power the vehicle, which reduces the amount of floor space and man-power required within the assembly plant for such testing. The source of electrical power for the system 10 includes a portable rechargeable lithium battery pack 40 and a current limiter 60. The current limiter 60 is adapted to control the power output of the battery pack 40 for protection of the electrical circuits of the vehicle. The current limiter 60 further includes a current monitor circuit 62 that is adapted to monitor the current flowing to and from the battery pack 40 and reduce EMI emissions, and a battery protection circuit 64 that is adapted to prevent overcharging and line surges that may damage the battery pack 40. The design of the current limiter 60 is based on “hot swap” capable integrated circuits with high heat dissipation to prevent excessive heat build-up and allow the system 10 operator to move quickly and efficiently between the vehicles on the assembly line.

The present invention has been described in an illustrative manner. It is to be understood that the terminology that has been used is intended to be in the nature of words of description rather than of limitation. Many modifications and variations of the present invention are possible in light of the above teachings. Therefore, the present invention may be practiced other than as specifically described.

What is claimed is:

1. A portable system for powering and testing the electrical circuits of a vehicle, said system comprising:
a source of electrical power adapted to power said portable system and to provide electrical power to the vehicle;
at least one power connector adapted to quickly connect/disconnect said portable system to/from the electrical system of the vehicle;
at least one diagnostic connector adapted to quickly connect/disconnect said portable system to/from the electrical circuits of the vehicle being tested;
a portable, low-power, sealed computing device adapted to perform testing on the electrical circuits of the vehicle; and
a vehicle-communications interface in electrical communication with said computing device and said at least one diagnostic connector, said interface adapted to provide electrical interface between said computing device and the electrical circuits of the vehicle.

2. A portable system as set forth in claim 1, wherein said source of electrical power includes a rechargeable four-cell lithium poly-battery pack.

3. A portable system as set forth in claim 1 which further includes a charging connector and a charging unit, said charging unit adapted to electrically connect to an electrical source and to said charging connector when said system is not connected to a vehicle such that said charging unit provides power to recharge said battery pack.

4. A portable system as set forth in claim 1 which further includes a bar code scanning unit adapted to scan and electrically recognize bar codes, and a scanner connector adapted to quickly connect/disconnect said scanning unit to/from said portable system.

5. The portable system as set forth in claim 1 which further includes an interface panel having electrical communication with said source of electrical power, said at least one power connector, said computing device, said vehicle communications interface, and said at least one diagnostic connector, said interface panel adapted to control the interface between said source of electrical power, said computing device, and said at least one power connector, and further adapted to control the interface between said computing device, said vehicle communications interface, and said at least one diagnostic connector.

6. The portable system as set forth in claim 5, wherein said interface panel further includes a current limiter in electrical communication with said electrical source and said at least one power connector, said current limiter adapted to control power output of said electrical source for protection of the electrical circuits of the vehicle.

7. The portable system as set forth in claim 6, wherein said current limiter further includes a current monitor circuit adapted to monitor the current flowing to and from said electrical source.

8. The portable system as set forth in claim 6, wherein said current limiter further includes a battery protection circuit adapted to prevent overcharging and line surges that may damage said electrical source.

9. A portable system as set forth in claim 1 which further includes an enclosure having packing material adapted to enclose said electrical source, said computing device, and said vehicle-communications interface, said packing material adapted to substantially pack and mount said electrical source, said computing device, and said vehicle-communications interface within said enclosure.

10. A portable system for powering and testing the electrical circuits of a vehicle, said system comprising:
a rechargeable battery pack adapted as a source of electrical power to power said portable system and to provide electrical power to the vehicle;
a portable, low-power, sealed computing device adapted to perform testing on the electrical circuits of the vehicle;
a vehicle-communications interface adapted to provide electrical communication between said computing device and the electrical circuits of the vehicle;
at least one power connector adapted to quickly connect/disconnect said portable system to/from the vehicle;
at least one diagnostic connector adapted to quickly connect/disconnect said portable system to/from the electrical circuits of the vehicle; and
an interface panel having electrical communication with said battery pack, said computing device, said vehicle-communications interface, said at least one power connector, and said at least one diagnostic connector, said interface panel adapted to control the interface between said battery pack, said computing device, and said at least one power connector, and further adapted to control the interface between said computing device, said vehicle communications interface, and said at least one diagnostic connector.

11. A portable system as set forth in claim 10 which further includes a charging connector and a charging unit, said charging unit adapted to electrically connect to an electrical source and to said charging connector when said system is not connected to a vehicle such that said charging unit provides power to recharge said battery pack.

12. A portable system as set forth in claim 11 which further includes a bar code scanning unit adapted to scan and electrically recognize bar codes, and a scanner connector adapted to quickly connect/disconnect said scanning unit to/from said portable system.

13. The portable system as set forth in claim 10, wherein said interface panel further includes a current limiter in electrical communication with said electrical source and said at least one power connector, said current limiter adapted to control power output of said electrical source for protection of the electrical circuits of the vehicle.

14. The portable system as set forth in claim 13, wherein said current limiter further includes a current monitor circuit adapted to monitor the current flowing to and from said electrical source.

15. The portable system as set forth in claim 13, wherein said current limiter further includes a battery protection circuit adapted to prevent overcharging and line surges that may damage said electrical source.

16. A portable system for powering and testing the electrical circuits of a vehicle, said system comprising:
a source of electrical power adapted to power said portable system and to provide electrical power to the vehicle;
at least one power connector adapted to quickly connect/disconnect said portable system to/from the vehicle such that said system can provide said electrical power and;
at least one diagnostic connector adapted to quickly connect/disconnect said portable system to/from the electrical circuits of the vehicle being tested;
a portable, low-power, sealed computing device adapted to perform testing on the electrical circuits of the vehicle; and
a vehicle-communications interface in electrical communication with said computing device and said at least one diagnostic connector, said interface adapted to provide electrical interface between said computing device and the electrical circuits of the vehicle;
an interface panel having electrical communication with said source of electrical power, said computing device, said vehicle-communications interface, said at least one power connector, and said at least one diagnostic connector, said interface panel adapted to control the interface between the source of electrical power, said computing device, and said at least one power connector, and further adapted to control the interface between said computing device, said vehicle-communications interface, and said at least one diagnostic connector; and
a current limiter in electrical communication with said source of electrical power and said at least one power connector, said current limiter adapted to control power output of said source of electrical power for protection of the electrical circuits of the vehicle.

17. A portable system as set forth in claim 16, wherein said source of electrical power includes a rechargeable four-cell lithium poly-battery pack.

18. A portable system as set forth in claim 17 which further includes a charging connector and a charging unit, said charging unit adapted to electrically connect to an electrical source and to said charging connector when said system is not connected to a vehicle such that said charging unit provides power to recharge said battery pack.

19. The portable system as set forth in claim 16, wherein said current limiter further includes a current monitor circuit adapted to monitor the current flowing to and from said electrical source, and a battery protection circuit adapted to prevent overcharging and line surges that may damage said electrical source.

20. A portable system as set forth in claim 16 which further includes an enclosure having packing material adapted to enclose said electrical source, said computing device, and said vehicle-communications interface, said packing material adapted to substantially pack and mount said electrical source, said computing device, and said vehicle-communications interface within said enclosure.
